(19) United States
(12) Patent Application Publication
(10) Pub. No.: US 2021/0171770 A1
(43) Pub. Date: Jun. 10, 2021

(54) RESIN COMPOSITION AND ARTICLE MADE THEREFROM

(71) Applicant: Elite Electronic Material (Zhongshan) Co., Ltd., Zhongshan City (CN)

(72) Inventors: Zhilong HU, Zhongshan City (CN); Teng XU, Zhongshan City (CN); Hezong ZHANG, Zhongshan City (CN)

(21) Appl. No.: 16/773,602

(22) Filed: Jan. 27, 2020

(30) Foreign Application Priority Data
Dec. 4, 2019 (CN) 201911227105.X

(51) Int. Cl. C08L 79/08; C08L 71/12

(52) U.S. Cl. CPC C08L 79/085; C08K 5/5403; C08L 71/12

(57) ABSTRACT

A resin composition includes a maleimide resin and a multifunctional vinylsilane. Also provided is an article made from the resin composition including such as a prepreg, a resin film, a laminate or a printed circuit board, wherein the article has improved one or more properties including glass transition temperature, difference in glass transition temperature, ratio of thermal expansion, peel strength, thermal resistance, dissipation factor and dissipation factor after ageing at high temperature.

### CROSS-REFERENCE TO RELATED APPLICATION

This application claims the priority benefits of China Patent Application No. 201911227105.X, filed on Dec. 4, 2019, the entirety of which is hereby incorporated by reference herein and made a part of this specification.

### BACKGROUND

### 1. Field of the Disclosure

The present disclosure mainly relates to a resin composition and more particularly to a resin composition comprising a maleimide resin and a multifunctional vinylsilane, which is useful for preparing an article such as a prepreg, a resin film, a laminate or a printed circuit board.

### 2. Description of Related Art

Low dielectric resin materials are important base materials in the electronic industry and are widely used in various servers, large base stations, cloud equipment and other electronic products.

Recently, the electronic technology has been developed towards high density, lower power consumption and higher performance, thereby presenting more challenges to the high performance electronic materials. Higher interconnection and integration density per unit area of electronic devices results in greater heat generation during the operation of the devices, which requires higher thermal resistance of the low dielectric resin materials including not only glass transition temperature but also time to thermal delamination and thermal resistance after moisture absorption of the materials. To increase the interconnectivity and installation reliability of the electronic devices, the materials need to achieve lower ratio of thermal expansion to ensure higher dimensional stability which is important to the alignment and positioning during the subsequent printed circuit board processes. In addition, the materials need to have sufficient adhesion strength to ensure strong connection with the metal traces and prevent failure due to separation of the traces. To realize long operation time of electronic products and transmission of big data, transmission speed of electronic information needs to be fast, and information transmission needs to be complete without signal loss, thereby presenting more demands on electronic properties of the materials. The materials need to have low dissipation factor, and preferably the dissipation factor is still low after ageing at high temperature without serious deterioration, so as to meet the needs of growing amount of electronic information data. In addition, lower difference in glass transition temperature of the materials indicates more complete curing which is an important feature to the stability of the products made therefrom.

### SUMMARY

To overcome the problems of prior arts, particularly one or more above-mentioned technical problems facing conventional materials, it is a primary object of the present disclosure to provide a resin composition and an article made therefrom which may overcome at least one of the above-mentioned technical problems.

Specifically, the resin composition disclosed herein achieves improvement in one or more of the following properties: prepreg or laminate glass transition temperature, difference in glass transition temperature (abbreviated as ATg), ratio of thermal expansion, peel strength (such as copper foil peeling strength), thermal resistance after moisture absorption, thermal resistance, dissipation factor, dissipation factor after ageing at high temperature, and dissipation factor decay.

To achieve the above-mentioned objects, the present disclosure provides a resin composition, comprising a maleimide resin; and a multifunctional vinylsilane comprising a compound of Formula (I), a compound of Formula (II), or a combination thereof:

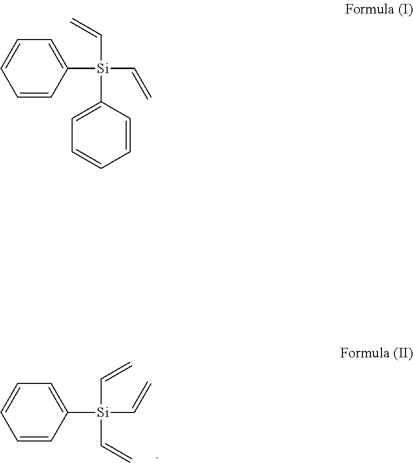 [SMILES: C=C[Si](C=C)(c1ccccc1)c1ccccc1 ; C=C[Si](C=C)(C=C)c1ccccc1]

In one embodiment, the present disclosure provides a resin composition, wherein the maleimide resin comprises 4,4′-diphenylmethane bismaleimide, oligomer of phenylmethane maleimide, m-phenylene bismaleimide, bisphenol A diphenyl ether bismaleimide, 3,3′-dimethyl-5,5′-diethyl-4,4′-diphenyl methane bismaleimide, 4-methyl-1,3-phenylene bismaleimide, 1,6-bismaleimide-(2,2,4-trimethyl)hexane, N-2,3-xylylmaleimide, N-2,6-xylyl maleimide, N-phenylmaleimide, maleimide resin containing aliphatic long-chain structure or a combination thereof.

In one embodiment, in the resin composition disclosed herein, if the maleimide resin is replaced by any specific maleimide resin described above or a combination thereof, articles made from the resin composition similarly achieve improvement in one or more of the following properties: glass transition temperature, difference in glass transition temperature (abbreviated as ATg), ratio of thermal expansion, peel strength (such as copper foil peeling strength), thermal resistance after moisture absorption, thermal resistance, dissipation factor, dissipation factor after ageing at high temperature, and dissipation factor decay.

In one embodiment, the resin composition according to the present disclosure may further optionally comprise a vinyl-containing polyphenylene ether resin. For example, the vinyl-containing polyphenylene ether resin may comprise a vinylbenzyl-terminated polyphenylene ether resin, a methacrylate-terminated polyphenylene ether resin or a combination thereof.

In one embodiment, the vinylbenzyl-terminated polyphenylene ether resin and the methacrylate-terminated polyphenylene ether resin respectively comprise a structure of Formula (III) and a structure of Formula (IV):

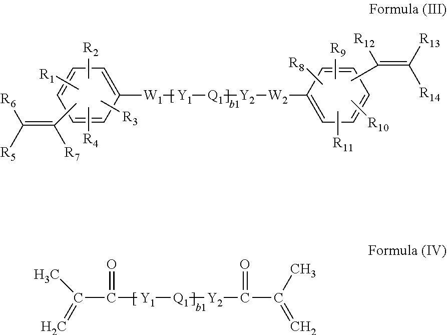

wherein R₁ to R₁₄ are individually H or —CH₃, and W₁ and W₂ are individually a C₁ to C₃ bivalent aliphatic group;
b1 is a natural number of 0 to 8;
Q₁ comprises a structure of any one of Formula (B-1) to Formula (B-3) or a combination thereof:

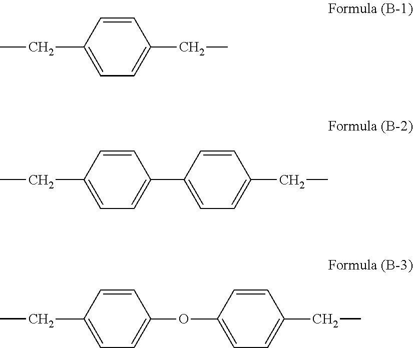

Y₁ and Y₂ independently comprise a structure of Formula (B-4):

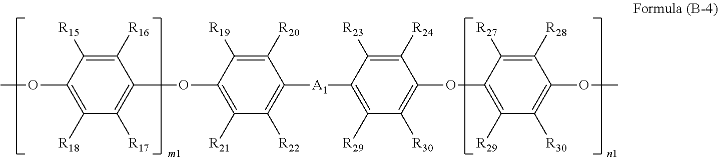

wherein R₁₅ to R₃₀ are independently H or —CH₃; m1 and n1 independently represent an integer of 1 to 30; and A₁ is selected from a covalent bond, —CH₂—, —CH(CH₃)—, —C(CH₃)₂—, —O—, —S—, —SO₂— and a carbonyl group.

In one embodiment, the resin composition disclosed herein may further optionally comprise a cyanate ester resin, a polyolefin resin, a small molecule vinyl compound, an acrylate resin, an epoxy resin, a phenolic resin, a benzoxazine resin, a styrene maleic anhydride resin, a polyester resin, an amine curing agent, a polyamide resin, a polyimide resin or a combination thereof.

In one embodiment, the resin composition disclosed herein may further optionally comprise flame retardant, inorganic filler, curing accelerator, polymerization inhibitor, solvent, toughening agent, silane coupling agent or a combination thereof.

In one embodiment, the resin composition disclosed herein comprises 10 parts by weight to 70 parts by weight of the maleimide resin and 10 parts by weight to 60 parts by weight of the multifunctional vinylsilane.

In one embodiment, the resin composition disclosed herein comprises 10 parts by weight to 60 parts by weight of the maleimide resin and 10 parts by weight to 50 parts by weight of the multifunctional vinylsilane.

In one embodiment, the resin composition disclosed herein comprises 10 parts by weight to 70 parts by weight of the maleimide resin, 10 parts by weight to 60 parts by weight of the multifunctional vinylsilane and 5 parts by weight to 50 parts by weight of the vinyl-containing polyphenylene ether resin.

In one embodiment, the resin composition disclosed herein comprises 10 parts by weight to 70 parts by weight of the maleimide resin, 10 parts by weight to 60 parts by weight of the multifunctional vinyl silane and 5 parts by weight to 40 parts by weight of the vinyl-containing polyphenylene ether resin.

In one embodiment, the resin composition disclosed herein comprises 10 parts by weight to 60 parts by weight of the maleimide resin, 10 parts by weight to 50 parts by weight of the multifunctional vinylsilane and 5 parts by weight to 50 parts by weight of the vinyl-containing polyphenylene ether resin.

In one embodiment, the resin composition disclosed herein comprises 10 parts by weight to 60 parts by weight of the maleimide resin, 10 parts by weight to 50 parts by weight of the multifunctional vinyl silane and 5 parts by weight to 40 parts by weight of the vinyl-containing polyphenylene ether resin.

Another main object of the present disclosure is to provide an article made from the aforesaid resin composition, and the article comprises a prepreg, a resin film, a laminate or a printed circuit board, but not limited thereto.

In one embodiment, articles made from the resin composition disclosed herein have one, more or all of the following properties:

high glass transition temperature as measured by reference to IPC-TM-650 2.4.24.4, such as the first glass transition temperature Tg1 being greater than or equal to 235° C., such as between 235° C. and 282° C. or between 235° C. and 280° C., the second glass transition temperature Tg2 being greater than or equal to 245° C., such as between 245° C. and 285° C. or between 245° C. and 281° C., or such as the first glass transition temperature Tg1 being greater than or equal to 255° C., such as between 255° C. and 270° C., and the second glass transition temperature Tg2 being greater than or equal to 258° C., such as between 258° C. and 272° C.;

the difference between the second glass transition temperature Tg2 and the first glass transition temperature Tg1 of the articles, denoted as the difference in glass transition temperature ΔTg, being less than or equal to 12° C., such as between 1° C. and 12° C. or between 1° C. and 10° C., or between 1° C. and 3° C.;

a ratio of thermal expansion as measured by reference to IPC-TM-650 2.4.24.5 of less than or equal to 1.70%, such as less than or equal to 1.60%, less than or equal to 1.35%, or between 0.95% and 1.70%, such as between 0.95% and 1.60% or between 1.20% and 1.35%;

a copper foil peeling strength as measured by reference to IPC-TM-650 2.4.8 of greater than or equal to 2.90 lb/in, such as greater than or equal to 3.35 lb/in, greater than or equal to 3.75 lb/in, or between 2.90 lb/in and 4.00 lb/in, such as between 3.35 lb/in and 4.00 lb/in or between 3.75 lb/in and 4.00 lb/in;

no delamination after subjecting the article to a thermal resistance test after moisture absorption by reference to IPC-TM-650 2.6.16.1 and IPC-TM-650 2.4.23;

a time to delamination as measured by using a thermomechanical analyzer by reference to IPC-TM-650 2.4.24.1 of greater than or equal to 70 minutes, such as between 70 minutes and 90 minutes;

a dissipation factor as measured by reference to JIS C2565 at 10 GHz of less than or equal to 0.0048, such as less than or equal to 0.0043 or less than or equal to 0.0042, such as between 0.0039 and 0.0048, between 0.0039 and 0.0043 or between 0.0039 and 0.0042;

a dissipation factor as measured by reference to JIS C2565 at 10 GHz after being subject to ageing at high temperature (e.g., after ageing at 150° C. for 24 hours) of less than or equal to 0.0052, such as less than or equal to 0.0048 or less than or equal to 0.0045, such as between 0.0044 and 0.0052, between 0.0044 and 0.0048 or between 0.0044 and 0.0045; and

a difference in dissipation factor after and before ageing at high temperature, denoted as dissipation factor decay, of less than or equal to 0.0011, such as less than or equal to 0.0007 or less than or equal to 0.0005, such as between 0.0003 and 0.0011, between 0.0003 and 0.0007 or between 0.0004 and 0.0005.

### DESCRIPTION OF THE EMBODIMENTS

To enable those skilled in the art to further appreciate the features and effects of the present disclosure, words and terms contained in the specification and appended claims are described and defined. Unless otherwise defined, all technical and scientific terms used herein have the same meaning as commonly understood by those of ordinary skill in the art to which this disclosure pertains. In the case of conflict, the present document and definitions contained herein will control.

As used herein, the term “comprises,” “comprising,” “includes,” “including,” “encompass,” “has,” “having” or any other variant thereof is construed as an open-ended transitional phrase intended to cover a non-exclusive inclusion. For example, a composition or manufacture that comprises a list of elements is not necessarily limited to only those elements but may include other elements not expressly listed or inherent to such composition or manufacture. Further, unless expressly stated to the contrary, the term “or” refers to an inclusive or and not to an exclusive or. For example, a condition “A or B” is satisfied by any one of the following: A is true (or present) and B is false (or not present), A is false (or not present) and B is true (or present), and both A and B are true (or present). In addition, whenever open-ended transitional phrases are used, such as “comprises,” “comprising,” “includes,” “including,” “encompass,” “has,” “having” or any other variant thereof, it is understood that transitional phrases such as “consisting essentially of” and “consisting of” are also disclosed and included.

In this disclosure, features or conditions presented as a numerical range or a percentage range are merely for convenience and brevity. Therefore, a numerical range or a percentage range should be interpreted as encompassing and specifically disclosing all possible subranges and individual numerals or values therein, particularly all integers therein. For example, a range of “1 to 8” should be understood as explicitly disclosing all subranges such as 1 to 7, 2 to 8, 2 to 6, 3 to 6, 4 to 8, 3 to 8 and so on, particularly all subranges defined by integers, as well as disclosing all individual values such as 1, 2, 3, 4, 5, 6, 7 and 8. Similarly, a range of “between 1 and 8” should be understood as explicitly disclosing all ranges such as 1 to 8, 1 to 7, 2 to 8, 2 to 6, 3 to 6, 4 to 8, 3 to 8 and so on and encompassing the end points of the ranges. Unless otherwise defined, the aforesaid interpretation rule should be applied throughout the present disclosure regardless of broadness of the scope.

Whenever amount, concentration or other numeral or parameter is expressed as a range, a preferred range or a series of upper and lower limits, it is understood that all ranges defined by any pair of the upper limit or preferred value and the lower limit or preferred value are specifically disclosed, regardless whether these ranges are explicitly described or not. In addition, unless otherwise defined, whenever a range is mentioned, the range should be interpreted as inclusive of the endpoints and every integers and fractions in the range.

Given the intended purposes and advantages of this disclosure are achieved, numerals or figures have the precision of their significant digits. For example, 40.0 should be understood as covering a range of 39.50 to 40.49.

As used herein, a Markush group or a list of items is used to describe examples or embodiments of the present disclosure. A skilled artisan will appreciate that all subgroups of members or items and individual members or items of the Markush group or list can also be used to describe the present disclosure. For example, when X is described as being “selected from a group consisting of X₁, X₂ and X₃,” it is intended to disclose the situations of X is X₁ and X is X₁ and/or X₂ and/or X₃. In addition, when a Markush group or a list of items is used to describe examples or embodiments of the present disclosure, a skilled artisan will understand that any subgroup or any combination of the members or items in the Markush group or list may also be used to describe the present disclosure. Therefore, for example, when X is described as being “selected from a group consisting of X₁, X₂ and X₃” and Y is described as being “selected from a group consisting of Y₁, Y₂ and Y₃,” the disclosure includes any combination of X is X₁ and/or X₂ and/or X₃ and Y is Y₁ and/or Y₂ and/or Y₃.

As used herein, part(s) by weight represents weight part(s) in any weight unit, such as but not limited to kilogram, gram, pound and so on. For example, 100 parts by weight of a vinyl-containing polyphenylene ether resin may represent 100 kilograms of the vinyl-containing polyphenylene ether resin or 100 pounds of the vinyl-containing polyphenylene ether resin.

The following embodiments and examples are illustrative in nature and are not intended to limit the present disclosure and its application. In addition, the present disclosure is not bound by any theory described in the background and summary above or the following embodiments or examples.

Unless otherwise specified, according to the present disclosure, a resin may include a compound and/or a mixture. A compound may include a monomer and/or a polymer. A mixture may include two or more compounds and may include a copolymer or auxiliaries, but not limited thereto.

For example, a compound refers to a chemical substance formed by two or more elements bonded with chemical bonds and may be present as a monomer, a polymer, etc., but not limited thereto. A monomer refers to a compound which may participate in a polymerization or prepolymerization reaction to produce a high molecular weight compound. A homopolymer refers to a chemical substance formed by a single compound via polymerization, addition polymerization or condensation polymerization, and a copolymer refers to a chemical substance formed by two or more compounds via polymerization, addition polymerization or condensation polymerization, but not limited thereto. In addition, as used herein, the term “polymer” includes but is not limited to an oligomer. An oligomer refers to a polymer with 2 to 20, typically 2 to 5, repeating units.

As described above, the present disclosure primarily aims to provide a resin composition, comprising: a maleimide resin; and a multifunctional vinylsilane comprising a compound of Formula (I), a compound of Formula (II), or a combination thereof:

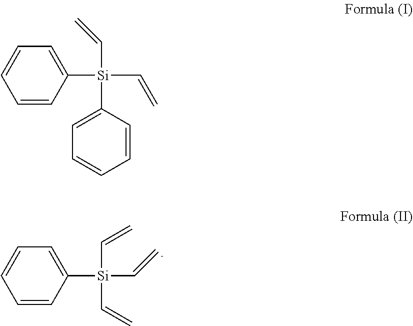 [SMILES: C=C[Si](C=C)(c1ccccc1)c1ccccc1 ; C=C[Si](C=C)(C=C)c1ccccc1]

For example, the multifunctional vinylsilane (a.k.a. multifunctional vinylsilane resin) used herein may be available from Suzhou Siso New Material Co., Ltd., such as but not limited to the multifunctional vinylsilane of CAS No. 17937-68-7 or 18042-57-4.

Unless otherwise specified, the multifunctional vinylsilane used herein contains at least two reactive carbon-carbon double bounds (C═C), such as two or three. In addition, unless otherwise specified, the multifunctional vinylsilane used herein does not contain and explicitly excludes a compound having only one reactive carbon-carbon double bound and does not contain and explicitly excludes a siloxane having a silicon-oxygen-silicon backbone structure.

For example, the maleimide resin used herein refers to a compound or a mixture containing at least one maleimide group. Unless otherwise specified, the maleimide resin used in the present disclosure is not particularly limited and may include any one or more maleimide resins useful for preparing a prepreg, a resin film, a laminate or a printed circuit board. Examples include but are not limited to 4,4′-diphenylmethane bismaleimide, oligomer of phenylmethane maleimide, m-phenylene bismaleimide, bisphenol A diphenyl ether bismaleimide, 3,3′-dimethyl-5,5′-diethyl-4,4′-diphenyl methane bismaleimide, 4-methyl-1,3-phenylene bismaleimide, 1,6-bismaleimide-(2,2,4-trimethyl)hexane, N-2,3-xylylmaleimide, N-2,6-xylylmaleimide, N-phenylmaleimide, maleimide resin containing aliphatic long-chain structure or a combination thereof. In addition, unless otherwise specified, the aforesaid maleimide resin of the present disclosure may also comprise a prepolymer thereof, such as a prepolymer of diallyl compound and maleimide resin, a prepolymer of diamine and maleimide resin, a prepolymer of multi-functional amine and maleimide resin or a prepolymer of acid phenol compound and maleimide resin, but not limited thereto.

For example, the maleimide resin may include products such as BMI-1000, BMI-1000H, BMI-1100, BMI-1100H, BMI-2000, BMI-2300, BMI-3000, BMI-3000H, BMI-4000H, BMI-5000, BMI-5100, BM-7000 and BMI-7000H available from Daiwakasei Co., Ltd., or products such as BMI-70 and BMI-80 available from K.I Chemical Industry Co., Ltd.

For example, the maleimide resin containing aliphatic long-chain structure may include products such as BMI-689, BMI-1400, BMI-1500, BMI-1700, BMI-2500, BMI-3000, BMI-5000 and BMI-6000 available from Designer Molecules Inc.

According to the present disclosure, unless otherwise specified, the amount or ratio of the maleimide resin and the multifunctional vinylsilane used in the resin composition is not particularly limited. In other words, the relative content of the maleimide resin and the multifunctional vinylsilane may be changed or adjusted if needed.

In one embodiment, the resin composition disclosed herein comprises 10 parts by weight to 70 parts by weight of the maleimide resin and 10 parts by weight to 60 parts by weight of the multifunctional vinylsilane.

In another embodiment, the resin composition disclosed herein comprises 10 parts by weight to 60 parts by weight of the maleimide resin and 10 parts by weight to 50 parts by weight of the multifunctional vinylsilane.

In one embodiment, in addition to the maleimide resin and the multifunctional vinylsilane, the resin composition disclosed herein may further optionally comprise: a vinyl-containing polyphenylene ether resin, a cyanate ester resin, a polyolefin resin, a small molecule vinyl compound, an acrylate resin, an epoxy resin, a phenolic resin, a benzoxazine resin, a styrene maleic anhydride resin, a polyester resin, an amine curing agent, a polyamide resin, a polyimide resin or a combination thereof.

For example, in one embodiment, the resin composition according to the present disclosure may further optionally comprise a vinyl-containing polyphenylene ether resin.

For example, according to the present disclosure, the vinyl-containing polyphenylene ether resin refers to a polyphenylene ether compound or mixture having an ethylenic carbon-carbon double bond (C═C) or a functional group derived therefrom, examples thereof including but not limited to the presence of a vinyl group, an allyl group, a vinylbenzyl group, a methacrylate group or the like in its structure. Unless otherwise specified, the position of the aforesaid functional group is not particularly limited and may be located at the terminal of a long-chain structure. In other words, the vinyl-containing polyphenylene ether resin described herein represents a polyphenylene ether resin containing a reactive vinyl group or a functional group derived therefrom, examples including but not limited to a polyphenylene ether resin containing a vinyl group, an allyl group, a vinylbenzyl group, or a methacrylate group.

In one embodiment, the vinyl-containing polyphenylene ether resin described herein comprises a vinylbenzyl-terminated polyphenylene ether resin, a methacrylate-terminated polyphenylene ether resin or a combination thereof.

For example, the vinylbenzyl-terminated polyphenylene ether resin refers to a polyphenylene ether resin with its terminal positions bonded to a vinylbenzyl group as shown below via an ether linkage.

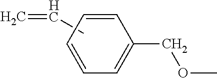

For example, the methacrylate-terminated polyphenylene ether resin refers to a polyphenylene ether resin with its terminals bonded to a methacrylate group.

In one embodiment, the vinylbenzyl-terminated polyphenylene ether resin and the methacrylate-terminated polyphenylene ether resin respectively comprise a structure of Formula (III) and a structure of Formula (IV):

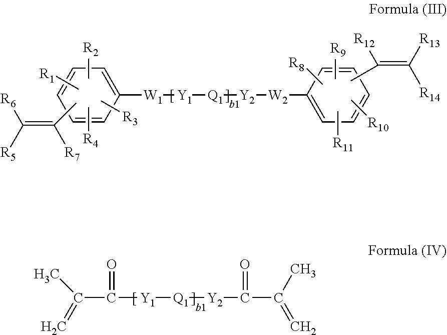

wherein R₁ to R₁₄ are individually H or —CH₃, and W₁ and W₂ are individually a C₁ to C₃ bivalent aliphatic group (e.g., methylene, ethylene, or propylene);
b1 is a natural number of 0 to 8, such as 0, 1, 2, 3, 4, 5, 6, 7 or 8;
Q₁ comprises a structure of any one of Formula (B-1) to Formula (B-3) or a combination thereof:

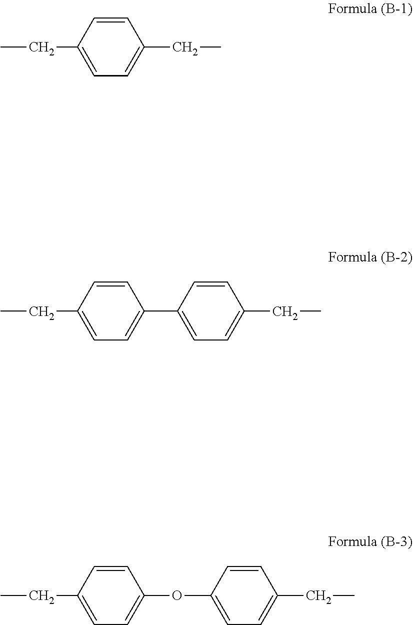

Y₁ and Y₂ independently comprise a structure of Formula (B-4):

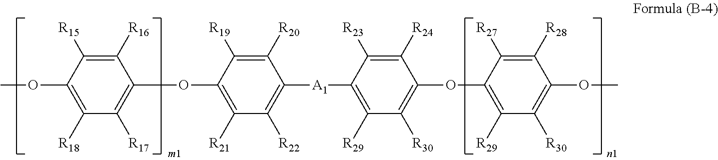

wherein R₁₅ to R₃₀ are independently H or —CH₃; m1 and n1 independently represent an integer of 1 to 30, such as 1, 5, 10, 15, 20, 25 or 30; and A₁ is selected from a covalent bond, —CH₂—, —CH(CH₃)—, —C(CH₃)₂—, —O—, —S—, —SO₂— and a carbonyl group.

In one embodiment, the aforesaid methacrylate-terminated polyphenylene ether resin is SA-9000 available from Sabic.

In one embodiment, the aforesaid vinylbenzyl-terminated polyphenylene ether resin is OPE-2st available from Mitsubishi Gas Chemical Co., Inc.

In one embodiment, the resin composition disclosed herein comprises 10 parts by weight to 70 parts by weight of the maleimide resin, 10 parts by weight to 60 parts by weight of the multifunctional vinylsilane and 5 parts by weight to 50 parts by weight of the vinyl-containing polyphenylene ether resin.

In another embodiment, the resin composition disclosed herein comprises 10 parts by weight to 70 parts by weight of the maleimide resin, 10 parts by weight to 60 parts by weight of the multifunctional vinylsilane and 5 parts by weight to 40 parts by weight of the vinyl-containing polyphenylene ether resin.

In one embodiment, the resin composition disclosed herein comprises 10 parts by weight to 60 parts by weight of the maleimide resin, 10 parts by weight to 50 parts by weight of the multifunctional vinylsilane and 5 parts by weight to 50 parts by weight of the vinyl-containing polyphenylene ether resin.

In one embodiment, the resin composition disclosed herein comprises 10 parts by weight to 60 parts by weight of the maleimide resin, 10 parts by weight to 50 parts by weight of the multifunctional vinyl silane and 5 parts by weight to 40 parts by weight of the vinyl-containing polyphenylene ether resin.

For example, the resin composition disclosed herein may further optionally comprise a cyanate ester resin, a polyolefin resin, a small molecule vinyl compound, an acrylate resin, an epoxy resin, a phenolic resin, a benzoxazine resin, a styrene maleic anhydride resin, a polyester resin, an amine curing agent, a polyamide resin, a polyimide resin or a combination thereof.

The cyanate ester resin used herein may include any known cyanate ester resins used in the art, including but not limited to a cyanate ester resin with an Ar—O—C≡N structure (wherein Ar represents an aromatic group, such as benzene, naphthalene or anthracene), a phenol novolac cyanate ester resin, a bisphenol A cyanate ester resin, a bisphenol A novolac cyanate ester resin, a bisphenol F cyanate ester resin, a bisphenol F novolac cyanate ester resin, a dicyclopentadiene-containing cyanate ester resin, a naphthalene-containing cyanate ester resin, a phenolphthalein cyanate ester resin, or a combination thereof. Examples of the cyanate ester resin include but are not limited to Primaset PT-15, PT-30S, PT-60S, BA-200, BA-230S, BA-3000S, BTP-2500, BTP-6020S, DT-4000, DT-7000, ULL950S, HTL-300, CE-320, LUT-50, or LeCy available from Lonza.

For example, the polyolefin resin used herein may include any one or more polyolefin resins useful for preparing a prepreg, a resin film, a laminate or a printed circuit board. Examples include but are not limited to styrene-butadiene-divinylbenzene terpolymer, styrene-butadiene-maleic anhydride terpolymer, vinyl-polybutadiene-urethane oligomer, styrene butadiene copolymer, hydrogenated styrene butadiene copolymer, styrene isoprene copolymer, hydrogenated styrene isoprene copolymer, methylstyrene homopolymer, petroleum resin, cycloolefin copolymer and a combination thereof.

For example, the small molecule vinyl compound as used herein refers to a vinyl-containing compound with a molecular weight of less than or equal to 1000, preferably between 100 and 900 and more preferably between 100 and 800. In one embodiment, the small molecule vinyl compound may include, but not limited to, divinylbenzene (DVB), bis(vinylbenzyl) ether (BVBE), bis(vinylphenyl)ethane (BVPE), triallyl isocyanurate (TAIC), triallyl cyanurate (TAC), 1,2,4-trivinyl cyclohexane (TVCH) or a combination thereof.

For example, the acrylate resin as used herein may include, but not limited to, tricyclodecane di(meth)acrylate, tri(meth)acrylate, 1,1′-[(octahydro-4,7-methano-1H-indene-5,6-diyl)bis(methylene)]ester (e.g., SR833S, available from Sartomer) or a combination thereof.

For example, the epoxy resin as used herein may be any epoxy resins known in the field to which this disclosure pertains, including but not limited to bisphenol A epoxy resin, bisphenol F epoxy resin, bisphenol S epoxy resin, bisphenol AD epoxy resin, novolac epoxy resin, trifunctional epoxy resin, tetrafunctional epoxy resin, multifunctional novolac epoxy resin, dicyclopentadiene (DCPD) epoxy resin, phosphorus-containing epoxy resin, p-xylene epoxy resin, naphthalene epoxy resin (e.g., naphthol epoxy resin), benzofuran epoxy resin, isocyanate-modified epoxy resin, or a combination thereof. The novolac epoxy resin may be phenol novolac epoxy resin, bisphenol A novolac epoxy resin, bisphenol F novolac epoxy resin, biphenyl novolac epoxy resin, phenol benzaldehyde epoxy resin, phenol aralkyl novolac epoxy resin or o-cresol novolac epoxy resin, wherein the phosphorus-containing epoxy resin may be DOPO (9,10-dihydro-9-oxa-10-phosphaphenanthrene-10-oxide) epoxy resin, DOPO-HQ epoxy resin or a combination thereof. The DOPO epoxy resin may be any one or more selected from DOPO-containing phenolic novolac epoxy resin, DOPO-containing cresol novolac epoxy resin and DOPO-containing bisphenol-A novolac epoxy resin; the DOPO-HQ epoxy resin may be any one or more selected from DOPO-HQ-containing phenolic novolac epoxy resin, DOPO-HQ-containing cresol novolac epoxy resin and DOPO-HQ-containing bisphenol-A novolac epoxy resin.

For example, the phenolic resin used herein may be a mono-functional, bifunctional or multi-functional phenolic resin. The type of the phenolic resin is not particularly limited and may include those currently used in the field to which this disclosure pertains. Preferably, the phenolic resin is selected from a phenoxy resin, a novolac resin and a combination thereof.

For example, the benzoxazine resin used herein may include bisphenol A benzoxazine resin, bisphenol F benzoxazine resin, phenolphthalein benzoxazine resin, dicyclopentadiene benzoxazine resin, or phosphorus-containing benzoxazine resin, such as but not limited to LZ-8270 (phenolphthalein benzoxazine resin), LZ-8280 (bisphenol F benzoxazine resin), and LZ-8290 (bisphenol A benzoxazine resin) available from Huntsman or HFB-2006M available from Showa High Polymer.

For example, the styrene maleic anhydride resin used herein may have a ratio of styrene (S) to maleic anhydride (MA) of 1:1, 2:1, 3:1, 4:1, 6:1, or 8:1, examples including but not limited to styrene maleic anhydride copolymers such as SMA-1000, SMA-2000, SMA-3000, EF-30, EF-40, EF-60 and EF-80 available from Cray Valley, or styrene maleic anhydride copolymers such as C400, C500, C700 and C900 available from Polyscope. In addition, the styrene maleic anhydride resin may also be an esterified styrene maleic anhydride copolymer, such as esterified styrene maleic anhydride copolymers SMA1440, SMA17352, SMA2625, SMA3840 and SMA31890 available from Cray Valley. Unless otherwise specified, the styrene maleic anhydride resin can be added individually or as a combination to the resin composition of this disclosure.

For example, the polyester resin used herein may be obtained by esterification of an aromatic compound with two carboxylic groups and an aromatic compound with two hydroxyl groups, such as but not limited to HPC-8000, HPC-8150 or HPC-8200 available from DIC Corporation.

For example, the amine curing agent used herein may be dicyandiamide, diamino diphenyl sulfone, diamino diphenyl methane, diamino diphenyl ether, diamino diphenyl sulfide or a combination thereof, but not limited thereto.

For example, the polyamide resin used herein may be any polyamide resin known in the field to which this disclosure pertains, including but not limited to various commercially available polyamide resin products.

For example, the polyimide resin used herein may be any polyimide resin known in the field to which this disclosure pertains, including but not limited to various commercially available polyimide resin products.

In one embodiment, in addition to the maleimide resin and the multifunctional vinylsilane, the resin composition disclosed herein may optionally further comprise flame retardant, inorganic filler, curing accelerator, polymerization inhibitor, solvent, toughening agent, silane coupling agent or a combination thereof.

In one embodiment, for example, the flame retardant used herein may be any one or more flame retardants useful for preparing a prepreg, a resin film, a laminate or a printed circuit board; examples of flame retardant include but are not limited to phosphorus-containing flame retardant, such as any one, two or more selected from the following group: ammonium polyphosphate, hydroquinone bis-(diphenyl phosphate), bisphenol A bis-(diphenylphosphate), tri(2-carboxyethyl) phosphine (TCEP), phosphoric acid tris(chloroisopropyl) ester, trimethyl phosphate (TMP), dimethyl methyl phosphonate (DMMP), resorcinol bis(dixylenyl phosphate) (RDXP, such as commercially available PX-200, PX-201, and PX-202), phosphazene (such as commercially available SPB-100, SPH-100, and SPV-100), melamine polyphosphate, DOPO and its derivatives or resins, diphenylphosphine oxide (DPPO) and its derivatives or resins, melamine cyanurate, tri-hydroxy ethyl isocyanurate, aluminium phosphinate (e.g., commercially available OP-930 and OP-935), or a combination thereof.

For example, the flame retardant used herein may be a DPPO compound (e.g., di-DPPO compound), a DOPO compound (e.g., di-DOPO compound), a DOPO resin (e.g., DOPO-HQ, DOPO-NQ, DOPO-PN, and DOPO-BPN), and a DOPO-containing epoxy resin, etc., wherein DOPO-PN is a DOPO-containing phenol novolac compound, and DOPO-BPN may be a DOPO-containing bisphenol novolac compound, such as DOPO-BPAN (DOPO-bisphenol A novolac), DOPO-BPFN (DOPO-bisphenol F novolac) or DOPO-BPSN (DOPO-bisphenol S novolac), etc.

In one embodiment, for example, the inorganic filler used herein may be any one or more inorganic fillers used for preparing a resin film, a prepreg, a laminate or a printed circuit board; examples include but are not limited to silica (fused, non-fused, porous or hollow type), aluminum oxide, aluminum hydroxide, magnesium oxide, magnesium hydroxide, calcium carbonate, aluminum nitride, boron nitride, aluminum silicon carbide, silicon carbide, titanium dioxide, zinc oxide, zirconium oxide, mica, boehmite (AlOOH), calcined talc, talc, silicon nitride, and calcined kaolin. Moreover, the inorganic filler can be spherical, fibrous, plate-like, particulate, sheet-like or whisker-like and can be optionally pretreated by a silane coupling agent.

In one embodiment, for example, the curing accelerator (including curing initiator) suitable for the present disclosure may comprise a catalyst, such as a Lewis base or a Lewis acid. The Lewis base may comprise any one or more of imidazole, boron trifluoride-amine complex, ethyltriphenyl phosphonium chloride, 2-methylimidazole (2MI), 2-phenyl-1H-imidazole (2PZ), 2-ethyl-4-methylimidazole (2E4MI), triphenylphosphine (TPP) and 4-dimethylaminopyridine (DMAP). The Lewis acid may comprise metal salt compounds, such as those of manganese, iron, cobalt, nickel, copper and zinc, such as zinc octanoate or cobalt octanoate. The curing accelerator also includes a curing initiator, such as a peroxide capable of producing free radicals, examples of curing initiator including but not limited to dicumyl peroxide, tert-butyl peroxybenzoate, dibenzoyl peroxide (BPO), 2,5-dimethyl-2,5-di(tert-butylperoxy)-3-hexyne (25B), bis(tert-butylperoxy isopropyl)benzene or a combination thereof.

In one embodiment, for example, the polymerization inhibitor is not particularly limited and may be any polymerization inhibitor known in the field to which this disclosure pertains, including but not limited to various commercially available polymerization inhibitor products.

In one embodiment, for example, the purpose of adding solvent is to change the solid content of the resin composition and to adjust the viscosity of the resin composition. For example, the solvent may comprise, but not limited to, methanol, ethanol, ethylene glycol monomethyl ether, acetone, butanone (methyl ethyl ketone), methyl isobutyl ketone, cyclohexanone, toluene, xylene, methoxyethyl acetate, ethoxyethyl acetate, propoxyethyl acetate, ethyl acetate, dimethylformamide, dimethylacetamide, propylene glycol methyl ether, or a mixture thereof.

In one embodiment, for example, the purpose of adding toughening agent is to improve the toughness of the resin composition. The toughening agent may comprise, but not limited to, carboxyl-terminated butadiene acrylonitrile rubber (CTBN rubber), core-shell rubber, or a combination thereof.

In one embodiment, for example, the silane coupling agent used herein may comprise silane (such as but not limited to siloxane) and may be further categorized according to the functional groups into amino silane compound, epoxide silane compound, vinylsilane compound, acrylate silane compound, methacrylate silane compound, hydroxylsilane compound, isocyanate silane compound, methacryloxy silane compound and acryloxy silane compound.

The resin composition of various embodiments may be processed to make different articles, such as those suitable for use as components in electronic products, including but not limited to a prepreg, a resin film, a laminate or a printed circuit board.

For example, the resin composition from each embodiment of this disclosure can be used to make a prepreg, which comprises a reinforcement material and a layered structure disposed thereon. The layered structure is formed by heating the resin composition at a high temperature to the semi-cured state (B-stage). Suitable baking temperature for making the prepreg may be for example 80° C. to 200° C. The reinforcement material may be any one of a fiber material, woven fabric, and non-woven fabric, and the woven fabric preferably comprises fiberglass fabrics. Types of fiberglass fabrics are not particularly limited and may be any commercial fiberglass fabric used for various printed circuit boards, such as E-glass fabric, D-glass fabric, S-glass fabric, T-glass fabric, L-glass fabric or Q-glass fabric, wherein the fiber may comprise yarns and rovings, in spread form or standard form. Non-woven fabric preferably comprises liquid crystal polymer non-woven fabric, such as polyester non-woven fabric, polyurethane non-woven fabric and so on, but not limited thereto. Woven fabric may also comprise liquid crystal polymer woven fabric, such as polyester woven fabric, polyurethane woven fabric and so on, but not limited thereto. The reinforcement material may increase the mechanical strength of the prepreg. In one preferred embodiment, the reinforcement material can be optionally pre-treated by a silane coupling agent. The prepreg may be further heated and cured to the C-stage to form an insulation layer.

For example, the resin composition from each embodiment of this disclosure can be used to make a resin film, which is prepared by heating and baking to semi-cure the resin composition. The resin composition may be selectively coated on a polyethylene terephthalate film (PET film), a polyimide film (PI film), a copper foil or a resin-coated copper, followed by heating and baking to semi-cure the resin composition to form the resin film.

For example, the resin composition from each embodiment of this disclosure can be used to make a laminate, which comprises two metal foils and an insulation layer disposed between the metal foils, wherein the insulation layer is made by curing the resin composition at high temperature and high pressure to the C-stage, a suitable curing temperature being for example between 150° C. and 220° C. and preferably between 200° C. and 210° C. and a suitable curing time being 90 to 180 minutes and preferably 120 to 150 minutes. The insulation layer may be formed by curing the aforesaid prepreg or resin film to the C-stage. The metal foil may comprise copper, aluminum, nickel, platinum, silver, gold or alloy thereof, such as a copper foil.

Preferably, the laminate is a copper-clad laminate (CCL).

In addition, the laminate may be further processed by trace formation processes to make a circuit board, such as a printed circuit board.

Preferably, the resin composition of the present disclosure or the article made therefrom may achieve improvement in one or more of the following properties: prepreg or laminate glass transition temperature, difference in glass transition temperature (ΔTg), ratio of thermal expansion, peel strength (such as copper foil peeling strength), thermal resistance after moisture absorption, thermal resistance, dissipation factor, dissipation factor after ageing at high temperature, and dissipation factor decay.

For example, the resin composition according to the present disclosure or the article made therefrom may achieve one, more or all of the following properties:

high glass transition temperature as measured by reference to IPC-TM-650 2.4.24.4, such as the first glass transition temperature Tg1 being greater than or equal to 235° C., such as between 235° C. and 282° C. or between 235° C. and 280° C., the second glass transition temperature Tg2 being greater than or equal to 245° C., such as between 245° C. and 285° C. or between 245° C. and 281° C., or such as the first glass transition temperature Tg1 being greater than or equal to 255° C., such as between 255° C. and 270° C., and the second glass transition temperature Tg2 being greater than or equal to 258° C., such as between 258° C. and 272° C.;

the difference between the second glass transition temperature Tg2 and the first glass transition temperature Tg1, denoted as the difference in glass transition temperature ΔTg, being less than or equal to 12° C., such as between 1° C. and 12° C. or between 1° C. and 10° C., or between 1° C. and 3° C.;

a ratio of thermal expansion as measured by reference to IPC-TM-650 2.4.24.5 of less than or equal to 1.70%, such as less than or equal to 1.60%, less than or equal to 1.35%, or between 0.95% and 1.70%, such as between 0.95% and 1.60% or between 1.20% and 1.35%;

a copper foil peeling strength as measured by reference to IPC-TM-650 2.4.8 of greater than or equal to 2.90 lb/in, such as greater than or equal to 3.35 lb/in, greater than or equal to 3.75 lb/in, or between 2.90 lb/in and 4.00 lb/in, such as between 3.35 lb/in and 4.00 lb/in or between 3.75 lb/in and 4.00 lb/in;

no delamination after subjecting the article to a thermal resistance test after moisture absorption by reference to IPC-TM-650 2.6.16.1 and IPC-TM-650 2.4.23;

a time to delamination as measured by using a thermomechanical analyzer by reference to IPC-TM-650 2.4.24.1 of greater than or equal to 70 minutes, such as between 70 minutes and 90 minutes;

a dissipation factor as measured by reference to JIS C2565 at 10 GHz of less than or equal to 0.0048, such as less than or equal to 0.0043 or less than or equal to 0.0042, such as between 0.0039 and 0.0048, between 0.0039 and 0.0043 or between 0.0039 and 0.0042;

a dissipation factor as measured by reference to JIS C2565 at 10 GHz after being subject to ageing at high temperature (e.g., after ageing at 150° C. for 24 hours) of less than or equal to 0.0052, such as less than or equal to 0.0048 or less than or equal to 0.0045, such as between 0.0044 and 0.0052, between 0.0044 and 0.0048 or between 0.0044 and 0.0045; and

a difference in dissipation factor after and before ageing at high temperature, denoted as dissipation factor decay, of less than or equal to 0.0011, such as less than or equal to 0.0007 or less than or equal to 0.0005, such as between 0.0003 and 0.0011, between 0.0003 and 0.0007 or between 0.0004 and 0.0005.

Raw materials below were used to prepare the resin compositions of various Examples and Comparative Examples of the present disclosure according to the amount listed in Table 1 to Table 4 and further fabricated to prepare test samples.

Materials and reagents used in Examples and Comparative Examples disclosed herein are listed below:

diphenyldivinylsilane: as shown by Formula (I), available from Suzhou Siso New Material Co., Ltd.
phenyltrivinylsilane: as shown by Formula (II), available from Suzhou Siso New Material Co., Ltd.
tetraphenyldivinylsiloxane: as shown by Formula (V):

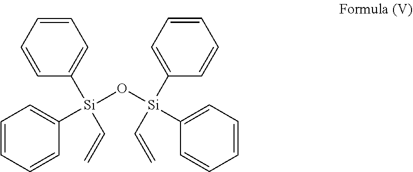 [SMILES: C=C[Si](O[Si](C=C)(c1ccccc1)c1ccccc1)(c1ccccc1)c1ccccc1]

RH-Vi321: vinylsiloxane, as shown by Formula (VI):

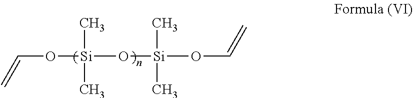

siloxane A: vinylsiloxane, as shown by Formula (VII):

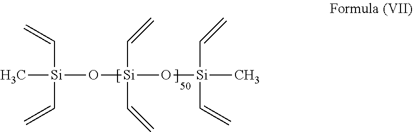

siloxane B: vinylsiloxane, as shown by Formula (VIII):

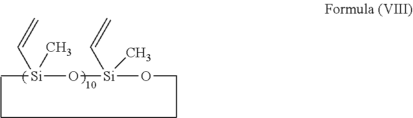

TAIC: triallyl isocyanurate, available from Kingyorker Enterprise Co., Ltd.
BMI-70: aromatic bismaleimide resin, available from K.I Chemical Industry Co., Ltd.
BMI-2300: polyphenylmethane maleimide, having vinyl groups as the reactive functional groups, available from Daiwakasei Industry Co., Ltd.
BMI-3000: maleimide resin containing aliphatic long-chain structure, available from Designer Molecules Inc.
BMI-4000: bisphenol A diphenyl ether bismaleimide, available from Daiwakasei Industry Co., Ltd.
SA-9000: methacrylate-terminated polyphenylene ether resin, available from Sabic.
OPE-2st: OPE-2st 2200, vinylbenzyl-terminated polyphenylene ether resin, available from Mitsubishi Gas Chemical Co., Inc.
KBM-1003: vinylsilane coupling agent having a structure of (CH₃O)₃SiCH═CH₂, available from Shin-Etsu Chemical Co., Ltd.
KBM-1403: styrylsilane coupling agent, having a structure of

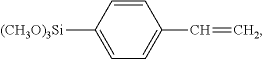

available from Shin-Etsu Chemical Co., Ltd.
Ricon 100: styrene-butadiene copolymer, available from Cray Valley.
SC-2500 SXJ: spherical silica pre-treated by amino silane coupling agent, available from Admatechs.
DCP: dicumyl peroxide, available from NOF Corporation.
methyl ethyl ketone: MEK, source not limited.
toluene: available from Chambeco Group.

Compositions of resin compositions of Examples and Comparative Examples are listed below (in part by weight):

TABLE 1
Resin compositions of Examples (in part by weight)

| Component | | E1 | E2 | E3 | E4 | E5 | E6 | E7 | E8 |
|---|---|---|---|---|---|---|---|---|---|
| multifunctional | diphenyldivinylsilane | 10 | 30 | 50 | 60 | 30 | 30 | 30 | |
| vinylsilane | phenyltrivinylsilane | | | | | | | | 30 |
| vinylsiloxane | tetraphenyldivinylsiloxane | | | | | | | | |
| | RH-Vi321 | | | | | | | | |
| | siloxane A | | | | | | | | |
| | siloxane B | | | | | | | | |
| crosslinking agent | TAIC | | | | | | | | |
| maleimide resin | BMI-70 | 30 | 30 | 30 | 30 | 10 | 60 | 70 | 30 |
| | BMI-2300 | | | | | | | | |
| vinyl-containing | SA-9000 | | | | | | | | |
| polyphenylene | OPE-2st | | | | | | | | |
| ether resin | | | | | | | | | |
| vinylsilane | KBM-1003 | | | | | | | | |
| coupling agent | | | | | | | | | |
| styrylsilane | KBM-1403 | | | | | | | | |
| coupling agent | | | | | | | | | |
| polyolefin | Ricon100 | 15 | 15 | 15 | 15 | 15 | 15 | 15 | 15 |
| inorganic filler | SC-2500 SXJ | 60 | 60 | 60 | 60 | 60 | 60 | 60 | 60 |
| curing accelerator | DCP | 0.5 | 0.5 | 0.5 | 0.5 | 0.5 | 0.5 | 0.5 | 0.5 |
| solvent | methyl ethyl ketone | PA | PA | PA | PA | PA | PA | PA | PA |
| | toluene | PA | PA | PA | PA | PA | PA | PA | PA |

Note:
PA represents “proper amount”.

TABLE 2
Resin compositions of Examples (in part by weight)

| Component | | E9 | E10 | E11 | E12 | E13 | E14 | E15 | E16 |
|---|---|---|---|---|---|---|---|---|---|
| multifunctional | diphenyldivinylsilane | 30 | 30 | 30 | 30 | 30 | 30 | 30 | 30 |
| vinylsilane | phenyltrivinylsilane | | | | | | | | |
| vinylsiloxane | tetraphenyldivinylsiloxane | | | | | | | | |
| | RH-Vi321 | | | | | | | | |
| | siloxane A | | | | | | | | |
| | siloxane B | | | | | | | | |
| crosslinking agent | TAIC | | | | | | | | |
| maleimide resin | BMI-70 | 30 | 30 | 30 | 30 | | 15 | 30 | 30 |
| | BMI-2300 | | | | | 30 | 15 | | |
| vinyl-containing | SA-9000 | 5 | 20 | 40 | 50 | | | | 20 |
| polyphenylene | OPE-2st | | | | | | | 40 | 20 |
| ether resin | | | | | | | | | |
| vinylsilane | KBM-1003 | | | | | | | | |
| coupling agent | | | | | | | | | |
| styrylsilane | KBM-1403 | | | | | | | | |
| coupling agent | | | | | | | | | |
| polyolefin | Ricon100 | 15 | 15 | 15 | 15 | 15 | 15 | 15 | 15 |
| inorganic filler | SC-2500 SXJ | 60 | 60 | 60 | 60 | 60 | 60 | 60 | 60 |
| curing accelerator | DCP | 0.5 | 0.5 | 0.5 | 0.5 | 0.5 | 0.5 | 0.5 | 0.5 |
| solvent | methyl ethyl ketone | PA | PA | PA | PA | PA | PA | PA | PA |
| | toluene | PA | PA | PA | PA | PA | PA | PA | PA |

TABLE 3
Resin compositions of Examples (in part by weight)

| Component | | E17 | E18 | E19 | E20 |
|---|---|---|---|---|---|
| multifunctional | diphenyldivinylsilane | 10 | 50 | 30 | 30 |
| vinylsilane | phenyltrivinylsilane | | | | |
| vinylsiloxane | tetraphenyl- | | | | |
| | divinylsiloxane | | | | |
| | RH-Vi321 | | | | |
| | siloxane A | | | | |
| | siloxane B | | | | |
| crosslinking agent | TAIC | | | | |
| maleimide resin | BMI-70 | 60 | 10 | 25 | |
| | BMI-2300 | | | | |
| | BMI-3000 | | | 5 | |
| | BMI-4000 | | | | 30 |
| vinyl-containing | SA-9000 | 20 | 20 | | |
| polyphenylene | OPE-2st | 20 | 20 | | |
| ether resin | | | | | |
| vinylsilane | KBM-1003 | | | | |
| coupling agent | | | | | |
| styrylsilane | KBM-1403 | | | | |
| coupling agent | | | | | |
| polyolefin | Ricon100 | 15 | 15 | 15 | 15 |
| inorganic filler | SC-2500 SXJ | 60 | 60 | 60 | 60 |
| curing accelerator | DCP | 0.5 | 0.5 | 0.5 | 0.5 |
| solvent | methyl ethyl ketone | PA | PA | PA | PA |
| | toluene | PA | PA | PA | PA |

TABLE 4
Resin compositions of Comparative Examples (in part by weight)

| Component | | C1 | C2 | C3 | C4 | C5 | C6 | C7 | C8 | C9 |
|---|---|---|---|---|---|---|---|---|---|---|
| multifunctional | diphenyldivinylsilane | 30 | | | | | | | | |
| vinylsilane | phenyltrivinylsilane | | | | | | | | | |
| vinylsiloxane | tetraphenyldivinylsiloxane | | | 30 | | | | | | |
| | RH-Vi321 | | | | 30 | | | | | |
| | siloxane A | | | | | 30 | | | | |
| | siloxane B | | | | | | 30 | | | |
| crosslinking agent | TAIC | | | | | | | 30 | | |
| maleimide resin | BMI-70 | | 30 | 30 | 30 | 30 | 30 | 30 | 30 | 30 |
| | BMI-2300 | | | | | | | | | |
| vinyl-containing | SA-9000 | | | | | | | | | |
| polyphenylene | OPE-2st | | | | | | | | | |
| ether resin | | | | | | | | | | |
| vinylsilane | KBM-1003 | | | | | | | | 30 | |
| coupling agent | | | | | | | | | | |
| styrylsilane | KBM-1403 | | | | | | | | | 30 |
| coupling agent | | | | | | | | | | |
| polyolefin | Ricon100 | 15 | 15 | 15 | 15 | 15 | 15 | 15 | 15 | 15 |
| inorganic filler | SC-2500 SXJ | 60 | 60 | 60 | 60 | 60 | 60 | 60 | 60 | 60 |
| curing accelerator | DCP | 0.5 | 0.5 | 0.5 | 0.5 | 0.5 | 0.5 | 0.5 | 0.5 | 0.5 |
| solvent | methyl ethyl ketone | PA | PA | PA | PA | PA | PA | PA | PA | PA |
| | toluene | PA | PA | PA | PA | PA | PA | PA | PA | PA |

Preparation of Varnish

Components of the resin composition from each Example (abbreviated as E, such as E1 to E20) or Comparative Example (abbreviated C, such as C1 to C9) were added to a stirrer according to the amounts listed in Tables 1-4 for stirring and well-mixing to form a resin varnish. For example, in Example E1, 10 parts by weight of diphenyldivinylsilane, 30 parts by weight of aromatic bismaleimide resin BMI-70 and 15 parts by weight of polyolefin Ricon100 were added to a stirrer containing a proper amount of toluene and a proper amount of methyl ethyl ketone (i.e., a proper amount of solvent suitable for obtaining a desired solid content, such as a solid content of the varnish being 65 wt %), and the solution was mixed and stirred to fully dissolve the solid ingredients to form a homogeneous liquid state. Then 60 parts by weight of spherical silica SC-2500 SXJ were added and well dispersed, followed by adding 0.5 part by weight of dicumyl peroxide (DCP, pre-dissolved by a proper amount of solvent) and stirring for 0.5 hour to obtain the varnish of resin composition E1 (solid content of 65 wt %).

In addition, according to the components and amounts listed in Table 1 to Table 4 above, varnishes of Examples E2 to E20 and Comparative Examples C1 to C9 were prepared following the preparation process of the varnish of Example E1.

On the other hand, resin compositions from Table 1 to Table 4 were used to make samples (specimens) as described below and tested under conditions specified below.

Prepreg (Using 2116 E-Glass Fiber Fabric)

Resin compositions from different Examples (E1 to E20) and Comparative Examples (C1 to C9) listed in Table 1 to Table 4 were respectively added to a stirred tank, well mixed and fully dissolved as varnishes and then added to an impregnation tank. A fiberglass fabric (e.g., 2116 E-glass fiber fabric) was passed through the impregnation tank to adhere the resin composition on the fiberglass fabric, followed by heating at 120° C. to 150° C. to the semi-cured state (B-Stage) to obtain the prepreg (resin content of about 52%).

Prepreg (Using 1080 E-Glass Fiber Fabric)

Resin compositions from different Examples (E1 to E20) and Comparative Examples (C1 to C9) listed in Table 1 to Table 4 were respectively added to a stirred tank, well mixed and fully dissolved as varnishes and then added to an impregnation tank. A fiberglass fabric (e.g., 1080 E-glass fiber fabric) was passed through the impregnation tank to adhere the resin composition on the fiberglass fabric, followed by heating at 120° C. to 150° C. to the semi-cured state (B-Stage) to obtain the prepreg (resin content of about 70%).

Copper-Clad Laminate (Obtained by Laminating Eight Prepregs)

Two 18 μm hyper very low profile 2 copper foils (HVLP2 copper foils) and eight prepregs made from each resin composition (using 2116 E-glass fiber fabric) were prepared batchwise. Each prepreg has a resin content of about 52%. A copper foil, eight prepregs and a copper foil were superimposed in such order and then subject to a vacuum condition for lamination at 200° C. for 2 hours to form each copper-clad laminate sample. Insulation layers were formed by curing (C-stage) eight sheets of superimposed prepreg between the two copper foils, and the resin content of the insulation layers was about 52%.

Copper-Free Laminate (Obtained by Laminating Eight Prepregs)

Each copper-clad laminate was etched to remove the two copper foils to obtain a copper-free laminate sample made from laminating eight prepregs, and each copper-free laminate had a resin content of about 52%.

Copper-Free Laminate (Obtained by Laminating Two Prepregs)

Two 18 μm hyper very low profile 2 copper foils (HVLP2 copper foils) and two prepregs made from each resin composition (using 1080 E-glass fiber fabric) were prepared batchwise. Each prepreg has a resin content of about 70%. A copper foil, two prepregs and a copper foil were superimposed in such order and then subject to a vacuum condition for lamination at 200° C. for 2 hours to form each copper-clad laminate, which was then subject to an etching process to remove the copper foils on both sides to obtain a copper-free laminate sample. Insulation layers were formed by curing (C-stage) two sheets of superimposed prepreg between the two copper foils, and the resin content of the insulation layers was about 70%.

Test items and test methods are described below.

1. Glass Transition Temperature (Tg)

A copper-free laminate (obtained by laminating eight prepregs) sample was subject to glass transition temperature measurement by using the dynamic mechanical analysis (DMA) method. Each sample was heated from 35° C. to 300° C. at a heating rate of 2° C./minute and then subject to the measurement of glass transition temperature (° C.) by reference to the method described in IPC-TM-650 2.4.24.4. The glass transition temperature of the copper-free laminate tested in the first round was recorded as Tg1. After the sample was cooled (about 35° C.), the glass transition temperature of the sample was tested again as described above. The glass transition temperature of the copper-free laminate tested in the second round was recorded as Tg2. Higher glass transition temperature is better.

For example, articles made from the resin composition disclosed herein are characterized by high glass transition temperature as measured by reference to IPC-TM-650 2.4.24.4, such as the first glass transition temperature Tg1 being greater than or equal to 235° C., the second glass transition temperature Tg2 being greater than or equal to 245° C., or such as the first glass transition temperature Tg1 being greater than or equal to 255° C., and the second glass transition temperature Tg2 being greater than or equal to 258° C.

2. Difference in Glass Transition Temperature (ΔTg)

The difference in glass transition temperature (ΔTg) is calculated as follow:

ΔTg=Tg2−Tg1

Tg1 represents the first glass transition temperature.

Tg2 represents the second glass transition temperature.

For example, articles made from the resin composition disclosed herein have low difference in glass transition temperature (ΔTg) as calculated above, such as ΔTg being less than or equal to 12° C. or less than or equal to 10° C. or less than or equal to 3° C.

Generally, lower ΔTg indicates more complete curing of the samples and higher stability of the products made therefrom. In the present technical field, a ΔTg of less than or equal to 5° C. represents complete curing and insubstantial difference in the property, but lower ΔTg is more preferred.

3. Ratio of Thermal Expansion

A copper-free laminate sample (obtained by laminating eight prepregs) was subject to thermal mechanical analysis (TMA) during the measurement of ratio of thermal expansion (i.e., ratio of dimensional change). Each sample was heated from 35° C. to 265° C. at a heating rate of 10° C./minute and then subject to the measurement of dimensional change (%) between 50° C. and 260° C. in Z-axis by reference to the method described in IPC-TM-650 2.4.24.5, wherein lower dimensional change percentage is more preferred.

In general, high ratio of thermal expansion in Z-axis indicates high ratio of dimensional change, and copper-clad laminates with high ratio of dimensional change may result in reliability problems such as delamination during printed circuit board fabrication. In the present technical field, lower ratio of thermal expansion is more preferred, and a difference in ratio of thermal expansion of greater than or equal to 0.1% represents a significant difference. For example, articles made from the resin composition disclosed herein have a ratio of thermal expansion as measured by reference to IPC-TM-650 2.4.24.5 of less than or equal to 1.70%, such as less than or equal to 0.95%, 1.00%, 1.08%, 1.10%, 1.15%, 1.20%, 1.21%, 1.25%, 1.30%, 1.32%, 1.35%, 1.40%, 1.45%, 1.50%, 1.55%, 1.60%, 1.65% or 1.70%, such as between 0.95% and 1.70%, between 0.95% and 1.60% or between 1.20% and 1.35%.

4. Copper Foil Peeling Strength (Peel Strength, P/S)

A copper-clad laminate (obtained by laminating eight prepregs) was cut into a rectangular specimen with a width of 24 mm and a length of greater than 60 mm, which was then etched to remove surface copper foil and leave a rectangular copper foil with a width of 3.18 mm and a length of greater than 60 mm. The specimen was tested by using a tensile strength tester by reference to IPC-TM-650 2.4.8 at ambient temperature (about 25° C.) to measure the force (lb/in) required to pull off the copper foil from the laminate surface. A higher copper foil peeling strength is more preferred, and a difference in copper foil peeling strength of greater than or equal to 0.1 lb/in represents a significant difference.

For example, articles made from the resin composition disclosed herein have a copper foil peeling strength as measured by reference to IPC-TM-650 2.4.8 of greater than or equal to 2.90 lb/in, preferably greater than or equal to 3.00 lb/in, 3.35 lb/in, 3.50 lb/in, 3.55 lb/in, 3.60 lb/in, 3.75 lb/in, 3.80 lb/in, 3.90 lb/in or 4.00 lb/in, such as between 2.90 lb/in and 4.00 lb/in, between 3.35 lb/in and 4.00 lb/in, or between 3.75 lb/in and 4.00 lb/in.

5. Thermal Resistance after Moisture Absorption (PCT)

Three copper-free laminate samples (obtained by laminating eight prepregs) were respectively subject to pressure cooking test (PCT) by reference to IPC-TM-650 2.6.16.1 and five hours of moisture absorption (testing temperature of 121° C., relative humidity of 100%), and then by reference to IPC-TM-650 2.4.23, the samples after moisture absorption were immersed into a 288° C. solder bath for 20 seconds, removed and then inspected to determine the absence or presence of delamination, such as whether interlayer delamination or blistering occurs between insulation layers. Interlayer delamination or blistering may occur between any layers of the laminate. Three samples were sequentially tested. The test is failed if delamination was observed in at least one sample, and the test is passed if delamination was not observed in all three samples. Designation with one “X” represents that delamination was observed in one sample, and designation with one “0” represents that delamination was not observed in one sample. The test result of the three samples was recorded. For example, a result of “XXX” represents that delamination was observed in all three samples, and a result of “000” represents that delamination was not observed in all three samples.

For example, articles made from the resin composition disclosed herein are characterized by no delamination in a thermal resistance test after moisture absorption by reference to IPC-TM-650 2.6.16.1 and IPC-TM-650 2.4.23.

6. T288 Thermal Resistance

A copper-clad laminate sample (obtained by laminating eight prepregs) was used in the T288 thermal resistance test. At a constant temperature of 288° C., a thermal mechanical analyzer (TMA) was used by reference to IPC-TM-650 2.4.24.1 to test each sample and record the time to delamination (e.g., blistering) of the copper-clad laminate. If no delamination was observed after 70 minutes of testing, a designation of “>70” was given.

For example, articles made from the resin composition disclosed herein are characterized by a time to delamination as measured by using a thermal mechanical analyzer by reference to IPC-TM-650 2.4.24.1 of greater than or equal to 70 minutes, such as between 70 minutes and 90 minutes.

7. Dissipation Factor (Df)

In the measurement of dissipation factor, a copper-free laminate sample (obtained by laminating two prepregs) was tested by using a microwave dielectrometer available from AET Corp. by reference to JIS C2565 at 10 GHz for analyzing each sample.

Under a 10 GHz frequency, for a Df value of less than or equal to 0.005, a difference in Df of less than 0.0001 represents no substantial difference in dissipation factor in different laminates, and a difference in Df of greater than or equal to 0.0001 represents a substantial difference (i.e., significant technical difficulty) in dissipation factor in different laminates. For a Df value of greater than 0.005, a difference in Df of less than 0.0003 represents no substantial difference in dissipation factor in different laminates, and a difference in Df of greater than or equal to 0.0003 represents a substantial difference (i.e., significant technical difficulty) in dissipation factor in different laminates.

For example, articles made from the resin composition disclosed herein have a dissipation factor as measured by reference to JIS C2565 at 10 GHz of less than or equal to 0.0048, such as less than or equal to 0.0043 or less than or equal to 0.0042.

8. Dissipation Factor after Ageing at High Temperature (Df after Ageing at High Temperature)

The aforesaid copper-free laminate sample (obtained by laminating two prepregs) was subject to the measurement of dissipation factor after ageing at high temperature. The sample was subject to ageing at 150° C. for 24 hours and then cooled to room temperature, followed by the measurement of dissipation factor by reference to JIS C2565 at 10 GHz. Under a 10 GHz frequency, for a Df value of less than or equal to 0.005, a difference in Df after ageing at high temperature of less than 0.0001 represents no substantial difference in dissipation factor after ageing at high temperature in different laminates, and a difference in Df after ageing at high temperature of greater than or equal to 0.0001 represents a substantial difference (i.e., significant technical difficulty) in dissipation factor after ageing at high temperature in different laminates. For a Df value after ageing at high temperature of greater than 0.005, a difference in Df after ageing at high temperature of less than 0.0003 represents no substantial difference in dissipation factor after ageing at high temperature in different laminates, and a difference in Df after ageing at high temperature of greater than or equal to 0.0003 represents a substantial difference (i.e., significant technical difficulty) in dissipation factor after ageing at high temperature in different laminates.

For example, articles made from the resin composition disclosed herein have a dissipation factor after ageing at high temperature as measured by reference to the method described above at 10 GHz of less than or equal to 0.0052, such as less than or equal to 0.0048 or less than or equal to 0.0045.

9. Dissipation Factor Decay (Df Decay)

The dissipation factor decay (Df decay) is calculated as follow:

dissipation factor decay=dissipation factor after ageing at high temperature—dissipation factor before ageing at high temperature (i.e., the dissipation factor as described above in Item No. 7) For example, articles made from the resin composition disclosed herein have a dissipation factor decay as measured by reference to the method described above of less than or equal to 0.0011, such as less than or equal to 0.0007 or less than or equal to 0.0005.

Results of the aforesaid tests of Examples and Comparative Examples are listed in Table 5 to Table 8 below:

TABLE 5
Test results of resin compositions of Examples

| Test Item | Unit | E1 | E2 | E3 | E4 | E5 | E6 | E7 | E8 |
|---|---|---|---|---|---|---|---|---|---|
| glass transition | ° C. | 265/266 | 273/275 | 270/272 | 268/280 | 261/264 | 280/281 | 282/285 | 275/277 |
| temperature | | | | | | | | | |
| difference in glass | ° C. | 1 | 2 | 2 | 12 | 3 | 1 | 3 | 2 |
| transition temperature | | | | | | | | | |
| ratio of thermal | % | 1.21 | 1.15 | 1.10 | 1.70 | 1.35 | 0.95 | 1.00 | 1.08 |
| expansion | | | | | | | | | |
| copper foil peeling | lb/in | 3.60 | 3.55 | 3.35 | 3.00 | 3.50 | 3.80 | 2.90 | 3.55 |
| strength | | | | | | | | | |
| PCT | none | ◯◯◯ | ◯◯◯ | ◯◯◯ | ◯◯◯ | ◯◯◯ | ◯◯◯ | ◯◯◯ | ◯◯◯ |
| T288 thermal resistance | min | >70 | >70 | >70 | >70 | >70 | >70 | >70 | >70 |
| dissipation factor | none | 0.0043 | 0.0042 | 0.0040 | 0.0040 | 0.0041 | 0.0043 | 0.0048 | 0.0041 |
| dissipation factor after | none | 0.0048 | 0.0046 | 0.0044 | 0.0051 | 0.0046 | 0.0046 | 0.0052 | 0.00445 |
| ageing at high | | | | | | | | | |
| temperature | | | | | | | | | |
| dissipation factor decay | none | 0.0005 | 0.0004 | 0.0004 | 0.0011 | 0.0005 | 0.0003 | 0.0004 | 0.00035 |

TABLE 6
Test results of resin compositions of Examples

| Test Item | Unit | E9 | E10 | E11 | E12 | E13 | E14 | E15 | E16 |
|---|---|---|---|---|---|---|---|---|---|
| glass transition | ° C. | 270/272 | 258/260 | 255/258 | 235/245 | 275/277 | 274/275 | 257/259 | 256/259 |
| temperature | | | | | | | | | |
| difference in glass | ° C. | 2 | 2 | 3 | 10 | 2 | 1 | 2 | 3 |
| transition temperature | | | | | | | | | |
| ratio of thermalexpansion | % | 1.20 | 1.30 | 1.35 | 1.60 | 1.10 | 1.15 | 1.32 | 1.32 |
| copper foil peeling strength | lb/in | 3.75 | 3.90 | 4.00 | 4.00 | 3.60 | 3.60 | 4.00 | 4.00 |
| PCT | none | ◯◯◯ | ◯◯◯ | ◯◯◯ | ◯◯◯ | ◯◯◯ | ◯◯◯ | ◯◯◯ | ◯◯◯ |
| T288 thermal resistance | min | >70 | >70 | >70 | >70 | >70 | >70 | >70 | >70 |
| dissipation factor | none | 0.0041 | 0.0039 | 0.0039 | 0.0039 | 0.00425 | 0.0042 | 0.00395 | 0.0039 |
| dissipation factor after | none | 0.0045 | 0.0044 | 0.0044 | 0.0046 | 0.0046 | 0.0046 | 0.0044 | 0.0044 |
| ageing at high temperature | | | | | | | | | |
| dissipation factor decay | none | 0.0004 | 0.0005 | 0.0005 | 0.0007 | 0.00035 | 0.0004 | 0.00045 | 0.0005 |

TABLE 7
Test results of resin compositions of Examples

| Test Item | Unit | E17 | E18 | E19 | E20 |
|---|---|---|---|---|---|
| glass transition | ° C. | 270/271 | 258/261 | 260/263 | 269/271 |
| temperature | | | | | |
| difference in | ° C. | 1 | 3 | 3 | 2 |
| glass transition | | | | | |
| temperature | | | | | |
| ratio of thermal | % | 1.20 | 1.30 | 1.20 | 1.19 |
| expansion | | | | | |
| copper foil | lb/in | 4.00 | 3.80 | 3.40 | 3.70 |
| peeling strength | | | | | |
| PCT | none | OOO | OOO | OOO | OOO |
| T288 thermal | min | >70 | >70 | >70 | >70 |
| resistance | | | | | |
| dissipation factor | none | 0.0042 | 0.0039 | 0.0041 | 0.0043 |
| dissipation factor | none | 0.0045 | 0.0043 | 0.0045 | 0.0047 |
| after ageing | | | | | |
| at high | | | | | |
| temperature | | | | | |
| dissipation factor | none | 0.0003 | 0.0004 | 0.0004 | 0.0004 |
| decay | | | | | |

TABLE 8
Test results of resin compositions of Comparative Examples

| Test Item | Unit | C1 | C2 | C3 | C4 | C5 | C6 | C7 | C8 | C9 |
|---|---|---|---|---|---|---|---|---|---|---|
| glass transition | ° C. | 215/232 | 250/255 | 245/250 | 230/236 | 240/248 | 245/255 | 220/235 | 230/239 | 235/242 |
| temperature | | | | | | | | | | |
| difference in glass | ° C. | 17 | 5 | 5 | 6 | 8 | 10 | 15 | 9 | 7 |
| transition temperature | | | | | | | | | | |
| ratio of thermal expansion | % | 2.00 | 1.60 | 1.50 | 2.00 | 1.80 | 1.70 | 1.70 | 2.02 | 2.05 |
| copper foil peeling | lb/in | 3.00 | 3.30 | 3.50 | 2.40 | 2.80 | 2.90 | 2.20 | 3.20 | 3.30 |
| strength | | | | | | | | | | |
| PCT | none | ◯XX | X◯◯ | ◯◯◯ | XXX | XXX | XXX | XXX | XXX | XXX |
| T288 thermal resistance | min | >70 | >70 | >70 | 20 | 40 | 45 | 15 | 10 | 10 |
| dissipation factor | none | 0.0034 | 0.0050 | 0.0050 | 0.0057 | 0.0060 | 0.0059 | 0.0044 | 0.0058 | 0.0059 |
| dissipation factor after | none | 0.0050 | 0.0059 | 0.0058 | 0.0064 | 0.0070 | 0.0070 | 0.0052 | 0.0071 | 0.0072 |
| ageing at high temperature | | | | | | | | | | |
| dissipation factor decay | none | 0.0016 | 0.0009 | 0.0008 | 0.0007 | 0.0010 | 0.0011 | 0.0008 | 0.0013 | 0.0013 |

The following observations can be made according to the test results above.

A side-by-side comparison of Examples E2 and E8 with Comparative Examples C3 (Formula (V)), C4 (Formula (VI)), C5 (Formula (VII)) and C6 (Formula (VIII)) confirms that, by using the multifunctional vinylsilane disclosed herein, laminates thus made may achieve a better electric property and high glass transition temperature and, in contrast to laminates made by using vinylsiloxane, may achieve at the same time the technical effects of lowering dissipation factor, lowering dissipation factor after ageing at high temperature, lowering dissipation factor decay, lowering Z-axis ratio of thermal expansion, increasing glass transition temperature (Tg1/Tg2), and lowering difference in glass transition temperature (ΔTg).

A side-by-side comparison of Examples E1 to E20 with Comparative Examples C1 and C2 confirms that, by using the resin composition disclosed herein comprising both a maleimide resin and a multifunctional vinylsilane, in contrast to using only the multifunctional vinylsilane (C1) or using only the maleimide resin (C2), laminates thus made may pass the PCT test (5 hr, dip 288° C., 20s), while Comparative Examples C1 and C2 fail to achieve the aforesaid technical effect.

A side-by-side comparison of Examples E1 to E20 with Comparative Example C7 confirms that, by using the multifunctional vinylsilane disclosed herein, in contrast to using a crosslinking agent of a vinyl compound (TAIC), laminates thus made may achieve one or more technical effects of increasing glass transition temperature, increasing peel strength (copper foil peeling strength), passing the PCT test (5 hr, dip 288° C., 20s) and increasing thermal resistance T288.

A side-by-side comparison of Examples E1 to E20 with Comparative Examples C8 and C9 confirms that, by using the multifunctional vinylsilane disclosed herein, in contrast to using a silane coupling agent containing a vinyl group or a styryl group, laminates thus made may achieve one or more technical effects of lowering Z-axis ratio of thermal expansion, passing the PCT test (5 hr, dip 288° C., 20s), increasing thermal resistance T288 and greatly lowering dissipation factor, dissipation factor after ageing at high temperature or dissipation factor decay.

Comparison of all Examples E1 to E20 with all Comparative Examples C1 to C9 disclosed herein confirms that laminates made by using the technical solution of the present disclosure may achieve at the same time one, more of all of the technical effects including a dissipation factor of less than or equal to 0.0048, a dissipation factor after ageing at high temperature of less than or equal to 0.0052, glass transition temperature Tg1 of greater than or equal to 235° C. and Tg2 of greater than or equal to 245° C., a difference in glass transition temperature of less than or equal to 12° C. and a Z-axis ratio of thermal expansion of less than or equal to 1.70%. In contrast, Comparative Examples C1 to C9 not using the technical solution of the present disclosure fail to achieve the aforesaid technical effects.

In addition, comparison of Example E4 (using 60 parts by weight of the multifunctional vinylsilane), Example E7 (using 70 parts by weight of the maleimide resin) and E12 (containing the vinyl-containing polyphenylene ether resin in an amount of 50 parts by weight) confirms that more desirable effects can be achieved by laminates made from other Examples, indicating that the amount of different components in the resin composition disclosed herein may be adjusted according to different needs.

The above detailed description is merely illustrative in nature and is not intended to limit the embodiments of the subject matter or the application and uses of such embodiments. As used herein, the term “exemplary” means “serving as an example, instance, or illustration.” Any implementation described herein as exemplary is not necessarily to be construed as more preferred or advantageous over other implementations.

Moreover, while at least one exemplary example or comparative example has been presented in the foregoing detailed description, it should be appreciated that a vast number of variations exist. It should also be appreciated that the exemplary one or more embodiments described herein are not intended to limit the scope, applicability, or configuration of the claimed subject matter in any way. Rather, the foregoing detailed description will provide those skilled in the art with a convenient guide for implementing the described one or more embodiments. Also, various changes can be made in the function and arrangement of elements without departing from the scope defined by the claims, which include known equivalents and foreseeable equivalents at the time of filing this patent application.

What is claimed is:

1. A resin composition, comprising:
a maleimide resin; and
a multifunctional vinylsilane, comprising a compound of Formula (I), a compound of Formula (II) or a combination thereof:

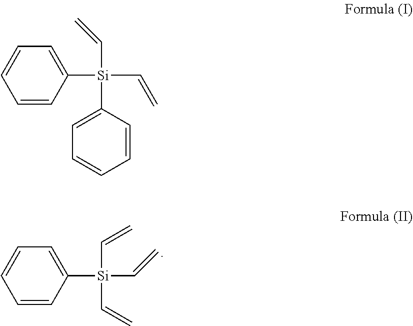 [SMILES: C=C[Si](C=C)(c1ccccc1)c1ccccc1 ; C=C[Si](C=C)(C=C)c1ccccc1]

2. The resin composition of claim 1, wherein the maleimide resin comprises 4,4′-diphenylmethane bismaleimide, oligomer of phenylmethane maleimide, m-phenylene bismaleimide, bisphenol A diphenyl ether bismaleimide, 3,3′-dimethyl-5,5′-diethyl-4,4′-diphenyl methane bismaleimide, 4-methyl-1,3-phenylene bismaleimide, 1,6-bismaleimide-(2,2,4-trimethyl) hexane, N-2,3-xylylmaleimide, N-2,6-xylylmaleimide, N-phenylmaleimide, maleimide resin containing aliphatic long-chain structure or a combination thereof.

3. The resin composition of claim 1, further comprising a vinyl-containing polyphenylene ether resin.

4. The resin composition of claim 3, wherein the vinyl-containing polyphenylene ether resin comprises a vinylbenzyl-terminated polyphenylene ether resin, a methacrylate-terminated polyphenylene ether resin or a combination thereof.

5. The resin composition of claim 4, wherein the vinylbenzyl-terminated polyphenylene ether resin and the methacrylate-terminated polyphenylene ether resin respectively comprise a structure of Formula (III) and a structure of Formula (IV): 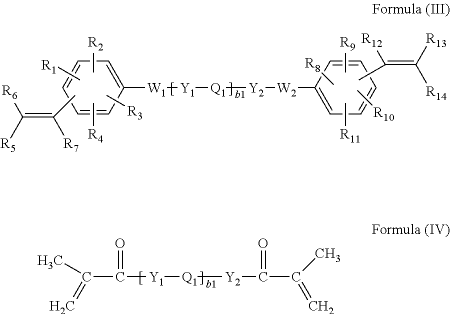
wherein R₁ to R₁₄ are individually H or —CH₃, and W₁ and W₂ are individually a C₁ to C₃ bivalent aliphatic group;
b1 is a natural number of 0 to 8;
Q₁ comprises a structure of any one of Formula (B-1) to Formula (B-3) or a combination thereof: 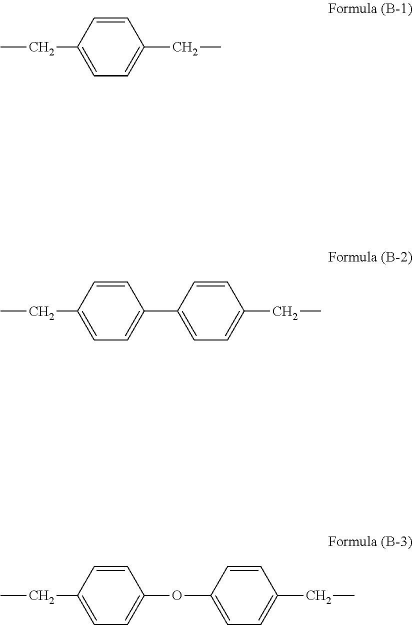
Y₁ and Y₂ independently comprise a structure of Formula (B-4): 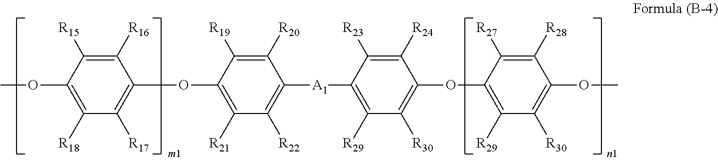
wherein R₁₅ to R₃₀ are independently H or —CH₃; m1 and n1 independently represent an integer of 1 to 30; and A₁ is selected from a covalent bond, —CH₂—, —CH(CH₃)—, —C(CH₃)₂—, —O—, —S—, —SO₂— and a carbonyl group.

6. The resin composition of claim 1, further comprising a cyanate ester resin, a polyolefin resin, a small molecule vinyl compound, an acrylate resin, an epoxy resin, a phenolic resin, a benzoxazine resin, a styrene maleic anhydride resin, a polyester resin, an amine curing agent, a polyamide resin, a polyimide resin or a combination thereof.

7. The resin composition of claim 1, further comprising flame retardant, inorganic filler, curing accelerator, polymerization inhibitor, solvent, toughening agent, silane coupling agent or a combination thereof.

8. The resin composition of claim 1, comprising 10 parts by weight to 70 parts by weight of the maleimide resin and 10 parts by weight to 60 parts by weight of the multifunctional vinylsilane.

9. The resin composition of claim 1, comprising 10 parts by weight to 60 parts by weight of the maleimide resin and 10 parts by weight to 50 parts by weight of the multifunctional vinylsilane.

10. The resin composition of claim 3, comprising 10 parts by weight to 70 parts by weight of the maleimide resin, 10 parts by weight to 60 parts by weight of the multifunctional vinylsilane and 5 parts by weight to 50 parts by weight of the vinyl-containing polyphenylene ether resin.

11. The resin composition of claim 10, wherein the vinyl-containing polyphenylene ether resin is 5 parts by weight to 40 parts by weight.

12. The resin composition of claim 9, further comprising 5 parts by weight to 50 parts by weight of the vinyl-containing polyphenylene ether resin.

13. The resin composition of claim 12, wherein the vinyl-containing polyphenylene ether resin is 5 parts by weight to 40 parts by weight.

14. An article made from the resin composition of claim 1, wherein the article comprises a prepreg, a resin film, a laminate, or a printed circuit board.

15. The article of claim 14, having a first glass transition temperature Tg1 and a second glass transition temperature Tg2 as measured by using dynamic mechanical analysis by reference to IPC-TM-650 2.4.24.4 of greater than or equal to 235° C. and greater than or equal to 245° C. respectively.

16. The article of claim 14, having a dissipation factor at 10 GHz as measured by reference to JIS C2565 of less than or equal to 0.0048.

17. The article of claim 14, having a dissipation factor at 10 GHz as measured by reference to JIS C2565 after being subject to ageing at 150° C. of less than or equal to 0.0052.

18. The article of claim 14, having a ratio of thermal expansion as measured by reference to IPC-TM-650 2.4.24.5 of less than or equal to 1.70%.
